(19) United States
(12) Patent Application Publication
(10) Pub. No.: US 2025/0132725 A1
(43) Pub. Date: Apr. 24, 2025

(54) PHOTOVOLTAIC THERMAL MODULE AND SOLAR SYSTEM

(71) Applicant: Sunmaxx PVT GmbH, Ottendorf-Okrilla (DE)

(72) Inventor: Wilhelm Stein, Dresden (DE)

(21) Appl. No.: 18/689,270

(22) PCT Filed: Aug. 12, 2022
(86) PCT No.: PCT/EP2022/072670

§ 371 Date: Mar. 28, 2024

(30) Foreign Application Priority Data
Sep. 6, 2021 (DE) 10 2021 123 000.4

(51) Int. Cl. H02S 40/42; F24T 10/10; F28F 3/12; F28F 21/00; F28F 21/08

(52) U.S. Cl. CPC H02S 40/425; F28F 3/12; F28F 21/006; F28F 21/08; F24T 10/10

(57) ABSTRACT

In an embodiment a photovoltaic-thermal module includes a plurality of solar cells and a planar heat sink, wherein the planar heat sink is based on at least one inorganic material and comprises a plurality of cooling channels, and wherein the planar heat sink extends partially or completely across the solar cells or parts of the solar cells.

### CROSS-REFERENCE TO RELATED APPLICATIONS

This patent application is a national phase filing under section 371 of PCT/EP2022/0762670, filed Aug. 12, 2022, which claims the priority of German patent application 102021123000.4, filed Sep. 6, 2021, each of which is incorporated herein by reference in its entirety.

### TECHNICAL FIELD

A photovoltaic-thermal module is specified. In addition, a solar system comprising such a photovoltaic-thermal module is provided.

### BACKGROUND

The publication U.S. Pat. No. 10,381,500 B2 relates to a photovoltaic module with integrated liquid cooling.

A hydraulic network for a heat sink is known from publication EP 1525 428 B1.

### SUMMARY

Embodiments provide a photovoltaic-thermal module that can be operated efficiently.

According to at least one embodiment, the photovoltaic-thermal module, PVT module for short, comprises a plurality of solar cells. The solar cells are based, for example, on silicon and/or germanium and/or a compound semiconductor material such as CdTe or CuInGaS, CIGS for short, or CuInS, CIS for short. The solar cells can also be based on perovskite or at least one organic photoactive material. In the case of thin-film modules, in particular those based on CdTe, CIGS, CIS, amorphous Si or perovskite, the photoactive layers are realized preferably as strips, for example with a width of at least 3 mm and/or at most 3 cm.

It is possible that several different types of solar cells or semiconductor materials are combined in the PVT module in order to achieve higher efficiency. For example, the individual, e.g. crystalline solar cells have an average diameter of at least 5 cm or at least 10 cm and/or at most 50 cm. The average diameter D results from an area A of the solar cell, for example, as follows: D=(4A/π)^{0.5}.

It is also possible for the cells to be halved or tripled and so on or cut into strips. This means that the crystalline solar cells do not represent squares or pseudo-squares, but rectangles.

According to at least one embodiment, the PVT module comprises one or more planar heat sinks. The preferably exactly one planar heat sink can also be referred to as a cooling panel or backside cooler. The planar heat sink is based on at least one inorganic material such as a glass or a metal, for example aluminum. The term ‘based on at least one inorganic material’ means, for example, that at least 80% by weight or at least 90% by weight or at least 98% by weight of the planar heat sink is formed by the at least one inorganic material. This does not exclude the possibility that small components of the planar heat sink, in particular mechanical components without any load-bearing function, such as seals or labels, may be formed from organic materials.

According to at least one embodiment, the planar heat sink comprises a plurality of cooling channels. The cooling channels are configured to allow a cooling liquid to flow through them.

According to at least one embodiment, the planar heat sink extends partially or completely across the solar cells or parts of the solar cells. For example, as seen in a top view of the PVT module, the planar heat sink is attached to at least 80% or at least 90% or at least 95% of an area of all solar cells taken together. This means that essentially the entire surface area of the solar cells can be bonded to the planar heat sink. It is possible that, for production reasons for example, the solar cells on an outer edge of the PVT module, as seen in top view, are only partially bonded to the planar heat sink. This means that there may be a surrounding edge around the PVT module that is devoid of the planar heat sink. The width of such an edge is, for example, at most 5 cm or at most 1 cm. Preferably, all solar cells are located completely on the planar heat sink.

According to at least one embodiment, the planar heat sink extends continuously across the respective solar cells or parts of solar cells. This means that one single common planar heat sink, which is devoid of gaps or holes, for example, is present in particular for all solar cells of the PVT module.

In at least one embodiment, the PVT module comprises a plurality of solar cells and a planar heat sink. The planar heat sink is based on at least one inorganic material, comprises a plurality of cooling channels for a cooling liquid and extends partially or completely, in particular continuously, across the solar cells or parts of the solar cells.

According to at least one embodiment, the planar heat sink comprises at least two panels or exactly two panels between which the cooling channels are formed. This makes it possible for the planar heat sink to be an enclosed, sealed system through which the cooling liquid can flow without any further components. In particular, the cooling channels are completely defined by the panels, optionally together with a connection means between the panels and/or for holding the panels together.

According to at least one embodiment, a first one of the panels, which faces the solar cells, is flat. Alternatively or additionally, a second one of the panels, which faces away from the solar cells, defines the cooling channels. This means that the cooling channels may be formed in the second panel.

According to at least one embodiment, the heat sink panels are formed by metal panels, for example by aluminum panels. Alternatively, the heat sink panels are formed by glass panels, so that the planar heat sink can be translucent. The connection means is then, for example, a metallic solder or a glass solder. All types of glass-glass bonding processes can also be used. Furthermore, lamination methods can be used, for example with structured lamination films that act in particular as connection means.

According to at least one embodiment, the planar heat sink is directly connected to a lamination film in which the solar cells are partially or completely embedded. The lamination film is, for example, an ethylene vinyl acetate film, or EVA film for short. Alternatively, one or more electrical isolation layers are located between the planar heat sink and the lamination film. It is possible that the isolation layer is directly adjacent to the lamination film and the planar heat sink.

According to at least one embodiment, the cooling channels have a branched structure. In other words, a single outflow and a single inflow can be provided for the planar heat sink, between which the cooling channels form a branched, flat structure.

According to at least one embodiment, an average distance between neighboring cooling channels amounts to at most 50% or at most 40% or at most 30% of the average diameter of the solar cells, as seen in top view of the solar cells. Alternatively or additionally, the cooling channels and thus an area for the cooling liquid each make up at least 20% or at least 50% of a base area of the solar cells.

According to at least one embodiment, an average distance between neighboring cooling channels amounts to at most 50% or at most 40% or at most 30% of a long side of the solar cells, as seen in top view of the solar cells. The long side corresponds to the longer side of rectangular solar cells. In particular, the cooling channels extend transversely to the long side.

According to at least one embodiment, the planar heat sink has a thickness of between (including) 1 mm and 10 cm or between (including) 1 mm and 3 cm or between (including) 2 mm and 12 mm. In this context, it is possible that a material thickness of the panels of the planar heat sink contributes to the thickness of the planar heat sink by at most 70% or at most 50% or at most 30%, so that the thickness of the planar heat sink can be determined to a large extent by the internal diameter of the cooling channels.

According to at least one embodiment, the planar heat sink mechanically supports the solar cells. This means that the PVT module can be devoid of a support frame surrounding the solar cells.

Furthermore, a solar system comprising such a PVT module as described in connection with one or more of the above embodiments is disclosed. Features of the PVT module are therefore also disclosed for the solar system, and vice versa.

In at least one embodiment, the solar system comprises at least one PVT module, a pumping device and an earth probe. The pumping device is configured to pump a cooling liquid through the at least one PVT module as well as through the earth probe.

In addition, an operating method for the solar system is provided in which the cooling liquid is pumped through the at least one PVT module as well as through the earth probe.

This means that the heat dissipated from the PVT module is not used in this case, but only serves to reduce the temperature of the PVT module. In this sense, the PVT module can be regarded as a pure PV module including a cooling system, as only electricity is generated, but no heat. The term PVT module preferably includes this.

In the following, a PVT module described herein, a solar system described herein and an operating method described herein are explained in more detail with reference to the drawing by means of exemplary embodiments. Identical reference signs indicate identical elements in the individual Figures. However, no references in relation to scales are shown; rather, individual elements may be shown in exaggerated size for better understanding.

### BRIEF DESCRIPTION OF THE DRAWINGS

In the Figures:

FIG. 1 is a schematic sectional view of a modification of a PVT module;

FIG. 2 is a schematic view from below of the PVT module of FIG. 1;

FIG. 3 is a schematic sectional view of an exemplary embodiment of a PVT module described here;

FIG. 4 is a schematic view from below of the PVT module of FIG. 3;

FIG. 5 is a schematic sectional view of an exemplary embodiment of a PVT module described here; and

FIG. 6 is a schematic sectional view of an exemplary embodiment of a solar system comprising PVT modules described here.

### DETAILED DESCRIPTION OF ILLUSTRATIVE EMBODIMENTS

Photovoltaic modules, PV modules for short, are already a pillar of the energy supply today and will become even more important in the future for fossil-free and CO₂-free energy supply. Costs have fallen by around 90% in the last ten years, making solar power the cheapest form of electricity generation in the world today. Nevertheless, a PV module today only converts around 20% of the irradiated solar energy into electricity, the rest is lost as waste heat.

For this reason, the question arises as to how this waste heat can be harnessed and how the overall efficiency of a PV module can be significantly increased. These modules, which address the heat, are known as photovoltaic-thermal modules or PVT modules for short. In addition to electrical energy, such PVT modules also produce heat, usually in the form of hot water. Copper coils are welded onto the back of a normal PV module, through which water and/or glycol as antifreeze is/are pumped. The incident solar radiation heats the water flowing through, which can then be used for other purposes.

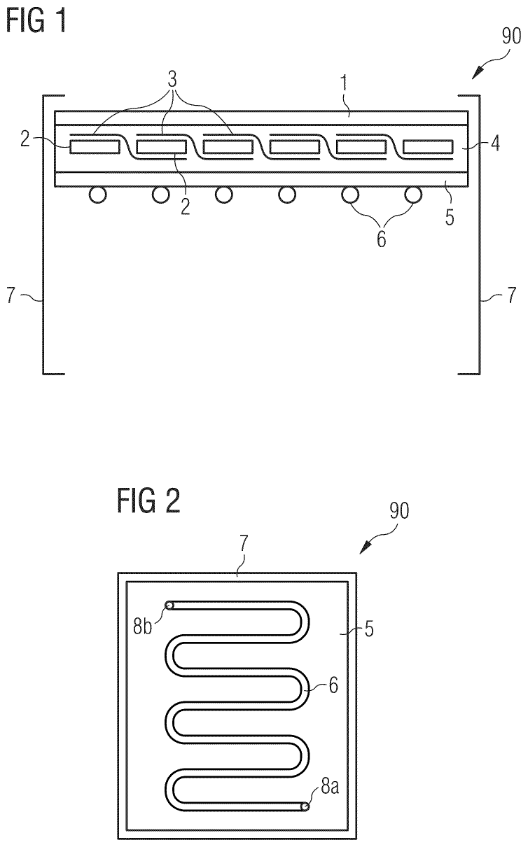

Such a modification of a PVT module 90 is illustrated in FIGS. 1 and 2. Several solar cells 2, for example crystalline solar cells, are connected to each other via electrical cell connectors 3 and are embedded in a lamination film 4, such as an EVA film. The lamination film 4 is located on a front glass 1. A rear wall film 5, for example a polyvinyl fluoride film, PVF film for short, such as a Tedlar film, or alternatively a rear glass, is located on a side of the lamination film 4 opposite the front glass 1. Copper tubes 6 serve as fluid carriers. The PVT module 90 is mechanically supported by a support frame 7, for example made of aluminum. A supply flow 8a for the still cold cooling liquid and a return flow 8b for the heated cooling liquid are attached to a rear side of the PVT module 90 for introducing and discharging a cooling liquid, not shown.

Various entry barriers prevent the widespread use of such PVT modules:

1. A high temperature operation at >60° C. causes the solar cells to heat up additionally and deliver less solar power than in normal operation.

2. Any technology involving welded copper tubes is difficult to scale and cannot be easily implemented in mass production, which means that the manufacturing costs are comparatively high.

3. The use of heat, especially in summer, when large quantities are available but demand tends to be low, is an additional market barrier.

4. The quality and efficiency of copper pipe technology for heat transfer is not very high.

With the advent of heat pumps for fossil-free heating of houses, apartments and buildings, various entry barriers have now been removed or lowered:

1. Modern PVT modules operate in a low-temperature mode at temperatures below approximately 40° C., hence providing cooling to the solar cells rather than heating them, meaning that this allows the solar module to generate more electricity rather than less.

2. When using heat pumps, the low-temperature heat can be used to increase a supply flow temperature and thus enable a more efficient operation.

However, the high costs and lack of scalability of the PVT modules including the copper tubes 6 described in FIGS. 1 and 2 represent a significant barrier to market entry. This problem is solved with the PVT modules 100 described here.

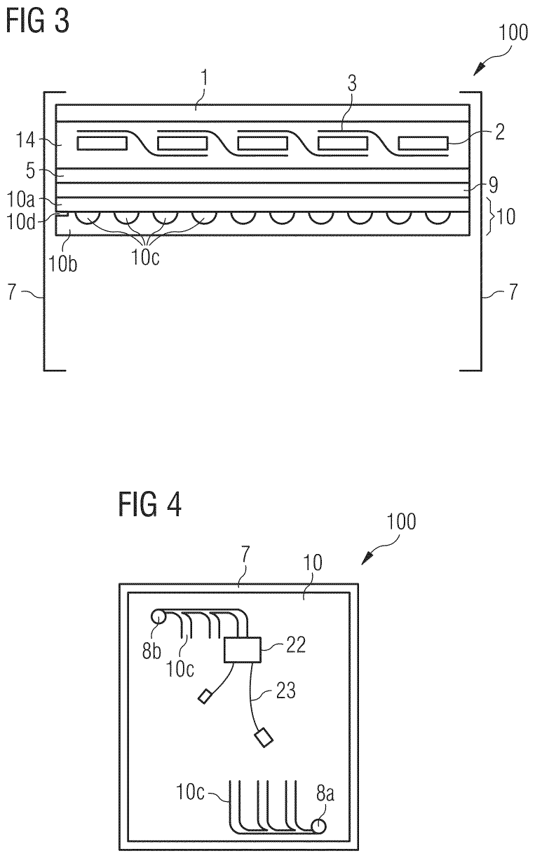

Part of the solution lies in particular in the fact that the copper tubes 6 on the back of the module 90 are replaced by a full-surface planar heat sink 10, in particular made of aluminum, see the PVT module 100 of FIGS. 3 and 4. Such planar heat sinks 10, also referred to as cooling panels, are used in automotive engineering, for example. The planar heat sink 10 typically consists of two thin aluminum sheets 10a, 10b and a connection means 10d; here, a channel structure with a large number of cooling channels 10c is embossed into one of the two panels 10b, for example by a stamping process. This highly efficient channel structure consists of many branches and is optimized to dissipate heat as efficiently as possible and to enable the lowest possible pressure losses.

After the stamping process, the embossed Al panel 10b is joined to the flat Al panel 10a in a special soldering process in an oven at high temperatures, in particular between 300° C. and 700° C., whereby the solder 10d is usually already applied on the Al panels before soldering. This then creates the Al cooling panel 10, which in turn is glued or laminated to the back of a PV laminate, in particular by means of an adhesion layer 9, which is made of an adhesive, for example, or is formed by another EVA film. A PV laminate is a PV module without a frame 7 and without an electrical junction box 22. It is also possible that a PV module with a junction box 22 but without a frame 7 is referred to as a PV laminate.

Subsequently, the junction box 22 is mounted, the frame 7 is attached and possibly a thermal insulation (not shown) made of foam or the like is applied to a side of the planar heat sink 10 facing away from the solar cells 2. Furthermore, the junction box 22 can optionally be provided with electrical connection cables 23 including a plug connector.

In addition to the extremely high efficiency of this PVT module 100 according to FIGS. 3 and 4, the high suitability for mass production and the associated perspective low costs are also a significant advance over the modification 90 shown in FIGS. 1 and 2.

The planar heat sink 10 of FIGS. 3 and 4 is based in particular on Al panels 10a, 10b, which have a thickness of 1 mm, for example. The internal diameters of the cooling channels 10c are, for example, 1 mm to 4 mm. A distance between adjacent cooling channels 10c is, for example, at least 4 mm and/or at most 20 mm. This can also apply to planar heat sinks 10 that are based on glass panels.

The cooling channels 10c can be comparatively wide at the supply flow 8a and the return flow 8b. The cooling channels 10c branch out at a large number of branches, which are in particular bifurcations or trifurcations, so that the width of the cooling channels 10c can decrease with increasing distance from the supply flow 8a and/or the return flow 8b.

It is possible for the thickness of the cooling channels 10c to be constant across the entire planar heat sink 10, regardless of the distance from the supply flow 8a and/or the return flow 8b, in order to realize a flat planar heat sink 10. For example, the cooling channels 10c have a semi-circular cross-section, with the flat side facing the solar cells.

In all other respects, the explanations regarding FIGS. 1 and 2 apply in the same way to FIGS. 3 and 4, and vice versa.

A further development of the design just described is the integration of the cooling panel 10 into the PVT modules 100, see FIG. 5. In this case, the cooling panel 10 is no longer subsequently connected to the finished PV laminate, but the cooling panel 10 completely replaces the normal rear side of the PV module. For example, PV modules with crystalline solar cells 2 have a rear side which usually is either a weather-resistant PVF film, which is usually white or black, or a transparent back glass, for example with a thickness of 2 mm. The back glass is particularly preferable if bifaciality of the PVT module 100 is desired.

The back glass or the PVF film is now completely replaced by the planar heat sink 10 in the PVT module 100 of FIG. 5. This means that after electrical connection, the solar cells 2 are no longer placed on the back glass or the PVF film before lamination, but directly on the planar heat sink 10. In other words, the planar heat sink 10 can be attached directly to the lamination film 4. The PVT module 100 comprises, for example, at least 50 and/or at most 250 of the solar cells 2, for example 60 or 72 solar cells with a size of 6 inches, or for example between (including) 120 and 144 half cells or even more cell strips.

The embedding of the solar cells 2 preferably takes place with the lamination film 4, such as an EVA film, which melts in the lamination process and embeds the solar cells 2 at the front and rear.

In order to avoid electrical arcing between the planar heat sink 10, which is based on electrically conductive aluminum, for example, and the solar cells 2 during operation, an additional highly insulating material is optionally present between the lamination film 4 and the planar heat sink 10 in an electrical isolation layer 11. For example, the electrical isolation layer 11 is made of at least one organic material, such as a plastic, for example polyethylene terephthalate, PET for short, or of at least one inorganic material, such as an oxide or nitride. In particular, the isolation layer 11 has a thickness of between (including) 0.1 mm and 1 mm in order to ensure low thermal resistance.

Alternatively, the lamination film 4 can also be replaced directly by an electrically highly insulating material, not shown, for example by a silicone or ionomer.

This means that the back glass or the PVF film can be dispensed with, eliminating the need for a separate, second lamination to apply the planar heat sink 10. This all saves costs, especially as the PVT module 100 is already mechanically very stable and a support frame 7 may no longer be required, which represents a further significant cost saving. In other words, the support frame 7, as shown in FIGS. 3 to 5, is merely optional.

The planar heat sink 10 can also be connected to thin-film modules based, for example, on CdTe, CIGS, a-Si, perovskite or an organic material. The planar heat sink 10 can be applied subsequently, as described above in the first exemplary embodiment of FIGS. 3 and 4, or the planar heat sink 10 can be integrated directly into the module 100. In the case of modules 100 in a so-called superstrate configuration, which are based in particular on Cd—Te or a-Si, the layer stack is deposited on the front glass of the solar module. Accordingly, the planar heat sink 10 can be laminated directly instead of the back glass. As CdTe modules are opaque anyway, i.e. have no bifaciality, this does not represent any deterioration in the case of free-standing PVT modules 100 for ground-mounted applications.

Modules 100 on the basis of copper indium gallium diselenide, or CIGS modules for short, on the other hand, are usually manufactured using substrate technology, whereby the layer stack with the solar cells 2 is applied to the back glass. Here, the back glass can be replaced directly by the planar heat sink 10, so that the latter acts as a substrate in the coating processes that are usually carried out under vacuum.

In a further embodiment, the planar heat sink 10 still comprises a highly efficient, branched channel structure, but the metal panels 10a, 10b are replaced by one or two glass layers 10a, 10b. The structure is preferably embossed directly during the manufacturing process of the glass after a float tank in the cooling process. This allows the PVT modules 100 to comprise a transparent planar heat sink 10, which also enables bifaciality. This can be particularly useful for large solar parks for ground-mounted applications. The glass-based planar heat sink 10 can be integrated into the PVT module 100 in various ways.

As in the case of the metallic panels 10a, 10b, the embossed back glass 10b is preferably bonded to a smooth glass 10a, for example by means of glass bonding, and then subsequently laminated as a whole onto a PV laminate. Alternatively, the glass-based planar heat sink 10 again serves as a substrate in the PV module lamination process and thus becomes an integral part of the PVT module 100. In order to increase the thermal conductivity, the flat glass 10a of the planar heat sink 10 can also be replaced by a transparent film, which is suitably bonded to the embossed cooler glass 10b provided with the channel structure 10c, for example by means of gluing. This composite 10a, 10b, 10d can then in turn become an integral part of the module manufacture as the rear side of the PVT module 100.

In all other respects, the explanations relating to FIGS. 1 to 4 apply in the same way to FIG. 5, and vice versa.

A further implementation relates to the operation of a solar system 111 with such back-cooled PVT modules 100 in ground-mounted systems, in particular in regions with high irradiation from the sun 20 and thus high ambient daytime temperatures, such as in parts of the USA, in Australia, North Africa, the Arabian Peninsula, India, or in desert regions in Central Asia, such as in China. The temperature coefficient of the PVT modules 100 results in high efficiency losses here. The modules 100 can easily reach temperatures of 70° C. to 80° C. or more in such climatic regions. This leads to electrical losses of up to 15% or up to 20% per year. By effectively cooling the PVT modules 100 with, for example, the AI-based or glass-based planar heat sink 10, the yield of such parks, which can be designed for outputs in the GW range, can be increased by the aforementioned 15% to 20%, which can correspond to sums in the double-digit to triple-digit million range per year, depending on the size of the solar park. In the case of glass-based planar heat sinks 10, it is even possible to combine the perfect cooling of the PVT module 100 with additional bifacial yield.

However, it is advantageous to have a heat sink that cools down the heated fluid flowing through the PVT modules 100. If there are flowing waters nearby, these can be used as follows: The cold water is extracted, flows through the PVT modules 100 for cooling and is returned slightly heated. The same can also be achieved using aquifers, for example with draw wells and absorption wells, if these are available. Furthermore, the flow-through in case of floating PV systems installed on large bodies of water, such as dams, can be integrated very elegantly in that the existing water on which the PVT modules 100 float is used for cooling.

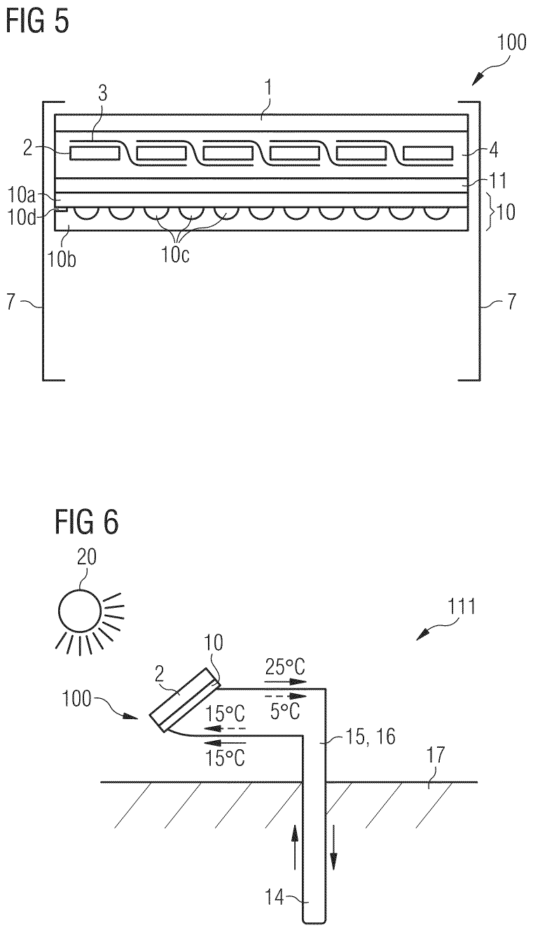

In most cases, however, as in deserts, there is no body of water available for cooling. Here, the soil is a suitable source of cooling, see FIG. 6. At a depth of 100 m to 150 m, for example, the soil 17 is normally at a constant temperature of around 10° C. to 15° C. The cooling liquid, for example water, previously heated to e.g. approximately 25° C. by the PVT modules 100, is passed through an earth probe 14 by means of a pumping device 15 and pipes 16 and is cooled in this process.

The cooling liquid can then be fed back into the PVT modules 100, for example at around 15° C., and cool them down, see the arrows with solid lines in FIG. 6. However, this causes the earth probe 14 to heat up more and more over time. The earth probe 14 must therefore be regenerated. This happens at night, for example. At night, the environment in desert regions usually cools down quickly to below 10° C. This allows the cool fluid to be passed through the earth probe 14 and cool and regenerate it again, see the arrows with dashed lines in FIG. 6. The next day, the earth probe 14 is available again for cooling the PVT modules 100.

Overall, the drilling of earth probes 14, the hydraulic piping and the use of planar heat sinks 10 as well as the pump current mean higher costs, which must be compensated for by the increased yield of the PVT modules 100 in order to provide an economical solution. Due to the long service life of solar systems 111 and PVT modules 100 of typically at least 30 years and the fact that cooling can be expected to have a positive effect on the ageing stability of the module components, so that the service life of the PVT modules 100 can then be up to 50 years or more, and due to the high additional annual income, it can be assumed that these additional investments will be amortized quickly.

Furthermore, it is possible to produce cold from heat by adsorption technology. Particularly in hot climatic regions, the conversion of the heat from a PVT module 100 into cold and its use for room cooling thus represents a further form of application. It should be noted here that higher temperatures of at least 50° C., for example, are often required for the efficient conversion of heat into cold. This can also be achieved by the PVT modules 100 described here, as the return flow temperature of the PVT module 100 can also be easily increased to these temperatures by reducing the flow rate. This high-temperature heat can then be stored in a high-temperature tank, for example; as soon as this tank is full, the PVT module 100 returns to power-efficient low-temperature operation via its controller. A refrigerating machine can then obtain the heat it requires from the high-temperature tank.

Otherwise, the explanations in FIGS. 1 to 5 apply in the same way to FIG. 6, and vice versa.

The fields of application for the PVT modules 100 described here include solar cells 2 of all types, for example crystalline or bifacial crystalline modules or thin-film modules. Furthermore, the following fields of application for the modules 100 are particularly suitable: rooftop, industrial, ground-mounted, low-temperature heating networks, floating systems, large ground-mounted solar parks, particularly in hot regions such as the USA, India, Spain, Arabia, Australia and Chile.

With the PVT modules 100 described here, the overall efficiency of solar modules can be increased from around 20% to up to 80% or more through combined electricity and heat production and utilization. This is particularly efficient for areas with limited space, such as house roofs, industrial roofs or commercial roofs, especially where there is a high demand for process heat. Furthermore, the combination with heat pumps for heating buildings is also preferred, which can lead to a significant increase in the annual coefficient of performance (COP) and an increase in the efficiency of the heat pump. Moreover, a higher electricity yield can be achieved through cooling, particularly in hot climates.

The invention described here is not limited by the description based on the exemplary embodiments. Rather, the invention includes any new feature as well as any combination of features, which includes in particular any combination of features in the claims, even if this feature or this combination itself is not explicitly stated in the claims or exemplary embodiments.

1.-11. (canceled)

12. A photovoltaic-thermal module comprising:
a plurality of solar cells; and
a planar heat sink,
wherein the planar heat sink is based on at least one inorganic material and comprises a plurality of cooling channels, and
wherein the planar heat sink extends partially or completely across the solar cells or parts of the solar cells.

13. The photovoltaic-thermal module of claim 12, wherein the planar heat sink comprises two panels between which the cooling channels are formed.

14. The photovoltaic-thermal module of claim 13, wherein a first one of the panels, which faces the solar cells, is flat, and wherein a second one of the panels, which faces away from the solar cells, defines the cooling channels.

15. The photovoltaic-thermal module of claim 13, wherein the heat sink panels are glass panels so that the planar heat sink is translucent.

16. The photovoltaic-thermal module of claim 13, wherein the heat sink panels are metal panels, which are connected to each other by a connection means.

17. The photovoltaic-thermal module of claim 12, wherein the planar heat sink is arranged directly on a lamination film in which the solar cells are embedded at least in part.

18. The photovoltaic-thermal module of claim 12,
wherein the solar cells are embedded in a lamination film at least in part, and
wherein an electrical isolation layer is arranged between the planar heat sink and the lamination film.

19. The photovoltaic-thermal module of claim 12, wherein the cooling channels form a branched structure, an average distance between neighboring cooling channels amounting to at most 50% of an average diameter of the solar cells, seen in top view, and/or at most 50% of an average long side of the solar cells, seen in top view.

20. The photovoltaic-thermal module of claim 12, wherein the solar cells are mechanically supported by the planar heat sink so that the photovoltaic-thermal module is devoid of a support frame surrounding the solar cells.

21. A solar system comprising:
at least one photovoltaic-thermal module of claim 12;
a pumping device; and
an earth probe,
wherein the pumping device is configured to pump a cooling liquid through the at least one photovoltaic-thermal module and through the earth probe.

22. A solar system comprising:
at least one photovoltaic-thermal module according to claim 12; and
a pumping device configured to pump water of a body of water as a cooling liquid through the at least one photovoltaic-thermal module,
wherein the solar system is configured to be arranged at least partially on the body of water.
